(19) United States
(12) Patent Application Publication
(10) Pub. No.: US 2012/0247392 A1
(43) Pub. Date: Oct. 4, 2012

(54) MULTICHAMBER THIN-FILM DEPOSITION APPARATUS AND GAS-EXHAUSTING MODULE

(75) Inventors: Cheng Chia FANG, Taipei City (TW); Cheng Chieh YANG, Taoyuan City (TW)

(73) Assignee: Pinecone Energies, Inc., Taipei City (TW)

(21) Appl. No.: 13/432,164

(22) Filed: Mar. 28, 2012

(30) Foreign Application Priority Data
Mar. 29, 2011 (TW) 100110855

(51) Int. Cl. C23C 16/458; B01D 45/16

(52) U.S. Cl. 118/729; 55/447; 55/459.1; 55/455

(57) ABSTRACT

A gas-exhausting module for a multichamber thin-film deposition apparatus, which has one or more reactor chambers, includes a collecting chamber and a plurality of gas pipes. The collecting chamber includes an upper portion and a lower portion. The cross-sectional area of the lower portion is less than the cross-sectional area of the upper portion. One end of each gas pipe communicates with one of the reactor chambers. The other end of each gas pipe communicates with the upper portion in a tangential direction. During operation, a cyclonic airflow is provided within the collecting chamber to uniformly extract the exhaust gas from each reactor chamber.

### CROSS-REFERENCE TO RELATED APPLICATIONS

The entire contents of Taiwan Patent Application No. 100110855, filed on Mar. 29, 2011, from which this application claims priority, are incorporated herein by reference.

### BACKGROUND OF THE INVENTION

1. Field of the Invention

The present invention relates to multichamber thin-film deposition apparatuses and their gas-exhausting modules.

2. Description of Related Art

Thin film deposition is a technology used to treat surfaces of various objects or components, such as semiconductor components. Using thin film technology, one or more thin films of one or more elements may be grown on the surface of substrates such as metals, alloys, ceramics, or semiconductor wafers.

The thin film deposition process may include chemical reactions to deposit thin films on the substrate. A physical vapor deposition (PVD) process is a thin film deposition process that does not include the use of a chemical reaction. A chemical vapor deposition (CVD) process is a thin film deposition process that uses one or more chemical reactions to deposit the thin film.

The crystal lattice of a grown (deposited) film may be single-crystalline, polycrystalline, or amorphous depending on the deposition technology and the process parameters. Epitaxy is an important process for growing single-crystalline films in fabricating integrated circuits. Because donors and acceptors can be directly doped during the deposition process, the dopant profile of the films semiconductor films grown by the epitaxy process can be precisely controlled. The films may also be grown to exclude oxygen, carbon, and other unwanted impurities from the films.

Metal-Organic Chemical Vapor Deposition (MOCVD) is a process to deposit a film on the surface of semiconductor wafer or other substrate. MOCVD employs a carrier gas to carry gaseous reactants or precursors into a reactor chamber loaded with substrates. A susceptor bears the substrates and uses a heating mechanism, such as electromagnetic wave induction heating or resistive heating, to heat the substrates and the gases approaching the substrates. As the temperature of the approaching gases is raised, one or more chemical reactions are triggered. The chemical reactions convert gaseous reactants into solid products to be deposited on the surfaces of the substrates.

The quality and yield rate of components formed by MOCVD depend on process conditions such as the stability of gas flow, temperature control, and gas control of the reactor chamber. Each of the above conditions will strongly affect the uniformity of the deposited films.

Because the chemical reactions occur at relatively high temperature, the temperature gradient generates natural convection and the gas-exhausting system generates forced convection. Both of these factors affect the uniformity of the deposited film. Therefore, it is desired to provide apparatuses or gas-exhausting systems that have the advantages of high treating capacity (high throughput), low cost, and ease of maintenance, as well as providing high uniformity in deposited films.

### SUMMARY OF THE INVENTION

Embodiments described herein relate to a gas-exhausting module for multichamber thin-film deposition systems. Certain embodiments relate to a gas-exhausting module with the advantages of high treating capacity, uniform gas flow, low cost, and ease of maintenance.

In certain embodiments, a gas-exhausting module for a multichamber thin-film deposition apparatus, which has one or more reactor chambers, includes a collecting chamber and a plurality of gas pipes. The collecting chamber may include an upper portion and a lower portion. The cross-sectional area of the lower portion may be less than the cross-sectional area of the upper portion. One end of each gas pipe may communicate with one of the reactor chambers. The other end of each gas pipe may communicate with an inlet of the upper portion in a tangential direction. During operation, the collecting chamber provides a cyclonic airflow to uniformly extract an exhaust gas from each reactor chamber.

### BRIEF DESCRIPTION OF THE DRAWINGS

Features and advantages of the methods and apparatus of the present invention will be more fully appreciated by reference to the following detailed description of presently preferred but nonetheless illustrative embodiments in accordance with the present invention when taken in conjunction with the accompanying drawings in which:

FIG. 1A shows an embodiment of a gas-exhausting module.

FIG. 1B is a top view of the gas-exhausting module of FIG. 1A.

FIG. 2A shows another embodiment of a gas-exhausting module.

FIG. 2B is a top view of the gas-exhausting module of FIG. 2A.

FIG. 3 depicts a block diagram of an embodiment of a multichamber thin-film deposition apparatus.

While the invention is susceptible to various modifications and alternative forms, specific embodiments thereof are shown by way of example in the drawings and will herein be described in detail. The drawings may not be to scale. It should be understood that the drawings and detailed description thereto are not intended to limit the invention to the particular form disclosed, but to the contrary, the intention is to cover all modifications, equivalents and alternatives falling within the spirit and scope of the present invention as defined by the appended claims.

### DESCRIPTION OF THE PREFERRED EMBODIMENT

Reference will now be made in detail to specific embodiments of the invention. Examples of these embodiments are illustrated in accompanying drawings. While the invention will be described in conjunction with these specific embodiments, it will be understood that it is not intended to limit the invention to these embodiments. On the contrary, it is intended to cover alternatives, modifications, and equivalents as may be included within the spirit and scope of the invention as defined by the appended claims. In the following description, numerous specific details are set forth in order to provide a thorough understanding of the present invention. The present invention may be practiced without some or all of these specific details. In other instances, well-known components and process operations are not described in detail in order not to unnecessarily obscure the present invention. While drawings are illustrated in detail, it is appreciated that the quantity of the disclosed components may be greater or less than that disclosed, except where expressly restricting the amount of the components.

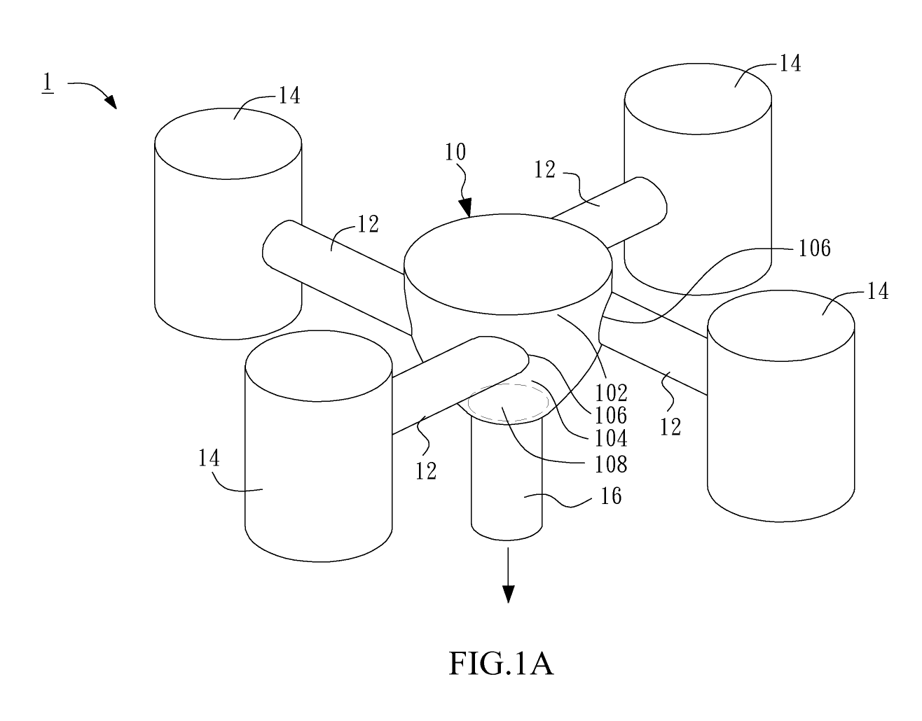

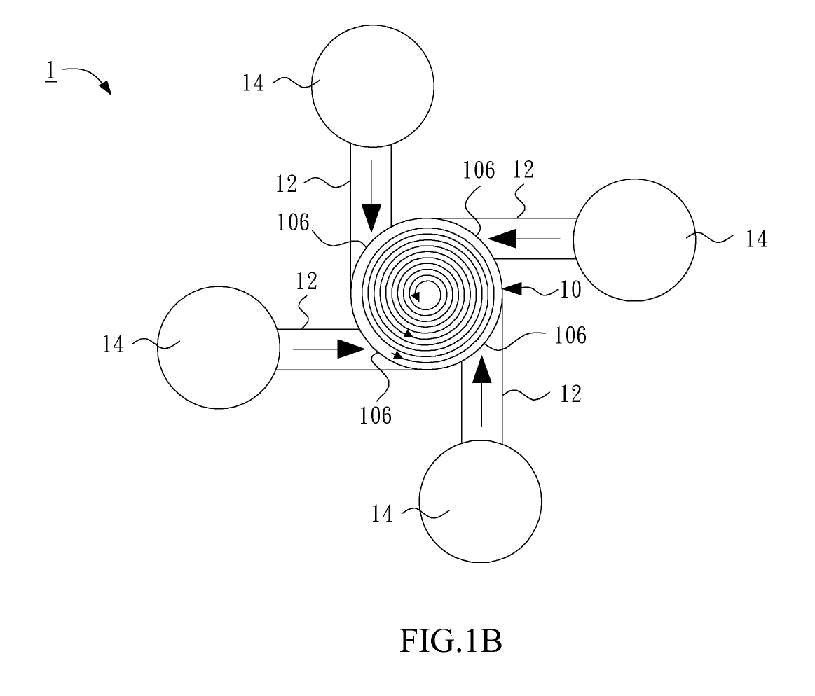

FIG. 1A and FIG. 1B show an embodiment of a gas-exhausting module, in which FIG. 1A is a perspective view and FIG. 1B is a top view. Gas-exhausting module 1 is suitable to be used in a multichamber thin-film deposition apparatus. In certain embodiments, the multichamber thin-film deposition apparatus is used for, but is not limited to use for, Metal-Organic Chemical Vapor Deposition (MOCVD).

Referring to FIG. 1A and FIG. 1B, gas-exhausting module 1 includes collecting chamber 10 and a plurality of gas pipes 12. Collecting chamber 10 is circular or round-like shaped (e.g., ellipse) as viewed from a top view angle. In certain embodiments, collecting chamber 10 includes upper portion 102 and lower portion 104. The cross-sectional area of upper portion 102 is greater than the cross-sectional area of lower portion 104. Gas pipes 12 connect to collecting chamber 10 and reactor chambers 14. In certain embodiments, a first end of each gas pipe 12 communicates to one of reactor chambers 14 and a second end of each gas pipe 12 communicates to one of inlets 106 on upper portion 102. In certain embodiments, each gas pipe 12 communicates to one of inlets 106 in a tangential direction on upper portion 102. For example, inlets 106 may be located off-center at or near the edges of upper portion 102 and the gas pipes are coupled to the inlets such that gas flows into the upper portion tangentially (e.g., the gas enters the upper portion off-axis (off-center or non-radially)).

In some embodiments, collecting chamber 10 includes outlet 108 arranged below lower portion 104 and communicating with exhaust pipe 16. Exhaust pipe 16 may communicate with a fan or a pump (not shown). It is noted that outlet 108 may be arranged at other positions of collecting chamber 10 and/or with other orientations. For example, outlet 108 and exhaust pipe 16 may be horizontally arranged instead of vertically arranged.

In certain embodiments, when gas-exhausting module 1 is in operation, collecting chamber 10 generates a cyclonic airflow to provide a uniform exhausting capacity for each of reactor chambers 14. The cyclonic airflow may be provided due to the gases entering collecting chamber 10 tangentially (e.g., off-center). Because of the cyclonic airflow in collecting chamber 10, exhaust gases of reactor chambers 14 may be uniformly extracted, the airflows inside the reactor chambers 14 may have substantially the same flow rate and the flow rates are steady. The substantially the same and steady flow rates may provide high uniformity of the deposited films in reactor chambers 14.

Typical multichamber thin-film deposition apparatus feature multiple gas-exhausting modules with each module communicating with one reactor chamber via an exhaust pipe. Because the exhaust gas includes particles such as un-reacted reactants, precursors, solid products, dust particles, and the like, these particles may be deposited on the walls within the reactor chamber and the exhaust pipes. The unwanted deposition of the particles may change the exhaust capacity. The exhaust capacity of one gas-exhausting module thus likely differs from others due to the unwanted deposition, thereby degrading the uniformity of the deposited films in the reactor chambers.

As shown in FIG. 1A, gas-exhausting module 1 employs collecting chamber 10 featuring a tapered shape with gas pipes 12 respectively communicating with all reactor chambers 14 in a tangential direction. The tapered shape of collecting chamber 10 in combination with gases entering the collecting chamber tangentially changes the pressure and flow rate of gases entering the collecting chamber and provides a cyclonic airflow within the collecting chamber. Because the cyclonic airflow is typically strong enough to avoid the influence of any particles on the walls of gas pipes 12 and cyclonic airflow is typically strong enough to uniformly extract exhaust gases from reactor chambers 14, the flow rates of each of the reactor chambers is steady and the flow rates of each reactor chamber is substantially the same. The steady and substantially similar flow rates may provide deposited films with high uniformity in the reactor chambers.

In certain embodiments, collecting chamber 10 is integrally formed. For example, as shown in FIG. 1A, collecting chamber 10 is integrally formed and has a bowl-like or a reversed conical profile. In some embodiments, the collecting chamber is formed from one or more parts. For example, the collecting chamber 10 may include an upper part and a lower part. The upper part may be a cylinder (surface) and the lower part may have a bowl-like or a reversed conical profile. In some embodiments, the collecting chamber includes an upper part that has a bowl-like or a reversed conical profile and a lower part that is a cylinder. In some embodiments, gas-exhausting module 1 includes a gas scrubber (not shown) arranged after the fan or pump or between the collecting chamber and the fan or pump.

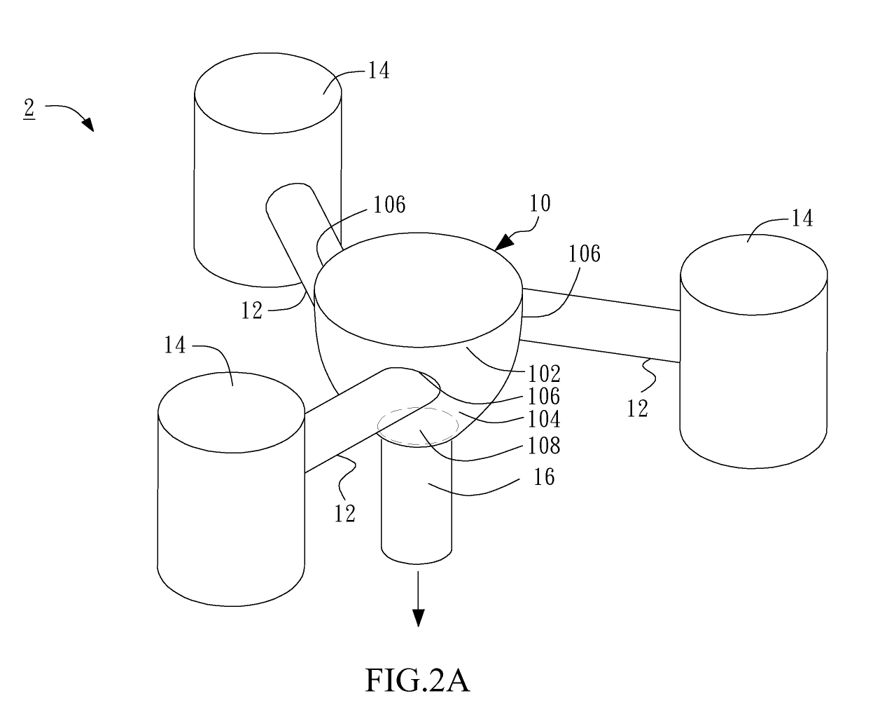

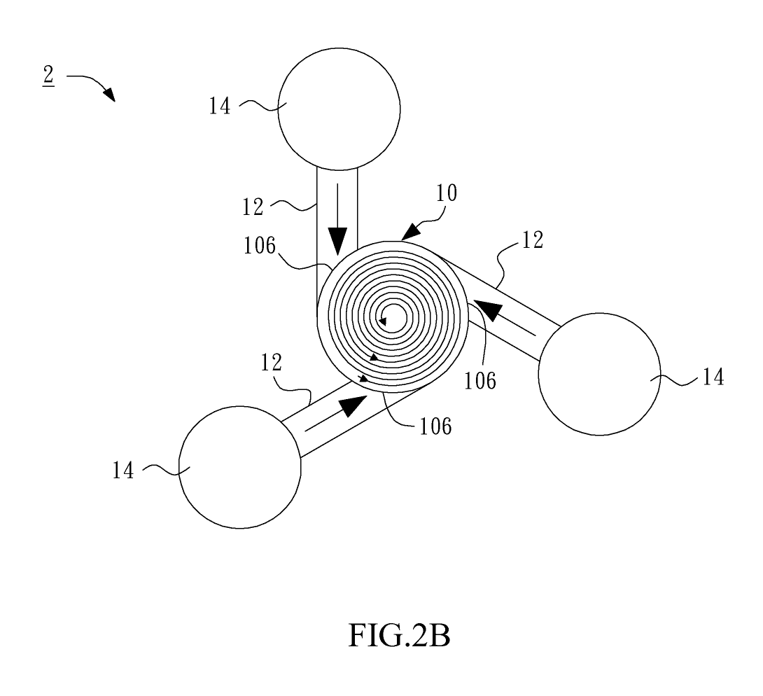

While FIGS. 1A and 1B depict an embodiment with four (4) reactor chambers 14, it is to be understood that the number of reactor chambers may vary. For example, there may be two (2), three (3), or five (5) reactor chambers. FIG. 2A and FIG. 2B show an embodiment of gas-exhausting module 2 that includes three reactor chambers 14. Collecting chamber 10 includes three inlets 106 with each inlet 106 communicating with one of reactor chambers 14 via one of gas pipes 12. The details, modifications, and alternatives of this embodiment are similar to those described for the embodiment of gas-exhausting module 1 described above and certain details have been omitted for simplicity and brevity.

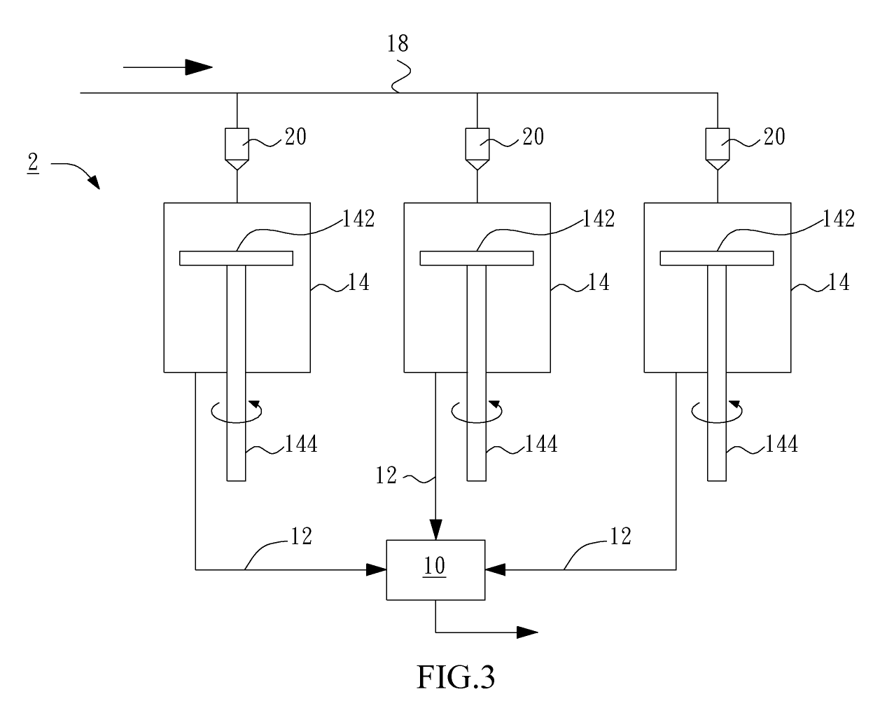

FIG. 3 depicts a block diagram of an embodiment of a multichamber thin-film deposition apparatus that includes the embodiment of gas-exhausting module 2 shown in FIGS. 2A and 2B. In certain embodiments, each reactor chamber 14 includes susceptor 142 for bearing substrates (e.g., semiconductor wafers) and driving module 144 for driving the susceptor. substrate may includes GaAs, Ge/SiGe, Si/SiC, Al/Al2O3, GaN, InN, MN, sapphire, glass or quartz. In some embodiments, feeding pipe 18 provides one or more gases for thin-film deposition and gas controller 20 is arranged between the feeding pipe and each reactor chamber 14 for controlling the gas flow rate. After thin-film deposition, collecting chamber 10 collects the exhaust gases of all reactor chambers 14 via gas pipes 12.

The embodiments of the gas-exhausting module described herein provide strong, steady, and uniform extracting capacity. Additionally, the module employs merely one collecting chamber to treat the exhaust gases of a plurality of reactor chambers, which reduces equipment and maintenance cost.

It is to be understood the invention is not limited to particular systems described which may, of course, vary. It is also to be understood that the terminology used herein is for the purpose of describing particular embodiments only, and is not intended to be limiting. As used in this specification, the singular forms “a”, “an” and “the” include plural referents unless the content clearly indicates otherwise. Thus, for example, reference to “a portion” includes a combination of two or more portions and reference to “a gas” includes mixtures of gases.

What is claimed is:

1. A gas-exhausting module for a multichamber thin-film deposition apparatus having one or more reactor chambers, comprising:
a collecting chamber comprising an upper portion and a lower portion, wherein a cross-sectional area of the lower portion is less than a cross-sectional area of the upper portion; and
a plurality of gas pipes, wherein a first end of each gas pipe communicates with one of the reactor chambers, and wherein a second end of each gas pipe communicates with an inlet on the upper portion;
wherein the collecting chamber provides a cyclonic airflow within the collecting chamber to uniformly extract exhaust gases from the reactor chambers during use.

2. The gas-exhausting module of claim 1, wherein the collecting chamber is circular or round-like shaped as viewed from a top view angle, and the second end of each gas pipe communicates with the inlet on the upper portion in a tangential direction.

3. The gas-exhausting module of claim 1, wherein each inlet is located off-center on the upper portion of the collecting chamber and the gas pipes are coupled to the inlets such that gas flows into the upper portion tangentially during use.

4. The gas-exhausting module of claim 1, wherein the collecting chamber is integrally formed.

5. The gas-exhausting module of claim 4, wherein the collecting chamber includes a bowl-like or a reversed conical profile.

6. The gas-exhausting module of claim 1, wherein the collecting chamber comprises an upper part and a lower part.

7. The gas-exhausting module of claim 6, wherein the upper part is a cylinder and the lower part has a bowl-like or a reversed conical profile.

8. The gas-exhausting module of claim 6, wherein the upper part has a bowl-like or a reversed conical profile, and the lower part is a cylinder.

9. The gas-exhausting module of claim 1, wherein the lower portion of the collecting chamber comprises an outlet communicating with an exhaust pipe.

10. The gas-exhausting module of claim 1, wherein the multichamber thin-film deposition apparatus is used for Metal-Organic Chemical Vapor Deposition.

11. A multichamber thin-film deposition apparatus, comprising:
a plurality of reactor chambers, each reactor chamber comprising a susceptor for bearing a plurality of substrates and a driving module for driving the susceptor;
a gas-exhausting module, comprising:
a collecting chamber, comprising an upper portion and a lower portion, wherein a cross-sectional area of the lower portion is less than a cross-sectional area of the upper portion; and
a plurality of gas pipes, wherein a first end of each gas pipe communicates with one of the reactor chambers, and wherein a second end of each gas pipe communicates with an inlet on the upper portion;
wherein the collecting chamber provides a cyclonic airflow within the collecting chamber to uniformly extract exhaust gases from the reactor chambers during use.

12. The multichamber thin-film deposition apparatus of claim 11, wherein the collecting chamber is circular or round-like shaped as viewed from a top view angle, and the second end of each gas pipe communicates with the inlet on the upper portion in a tangential direction.

13. The multichamber thin-film deposition apparatus of claim 11, wherein each inlet is located off-center on the upper portion of the collecting chamber and the gas pipes are coupled to the inlets such that gas flows into the upper portion tangentially during use.

14. The multichamber thin-film deposition apparatus of claim 11, wherein the collecting chamber is integrally formed.

15. The multichamber thin-film deposition apparatus of claim 14, wherein the collecting chamber includes a bowl-like or a reversed conical profile.

16. The multichamber thin-film deposition apparatus of claim 11, wherein the collecting chamber comprises an upper part and a lower part.

17. The multichamber thin-film deposition apparatus of claim 16, wherein the upper part is a cylinder and the lower part has a bowl-like or a reversed conical profile.

18. The multichamber thin-film deposition apparatus of claim 16, wherein the upper part has a bowl-like or a reversed conical profile, and the lower part is a cylinder.

19. The multichamber thin-film deposition apparatus of claim 11, wherein the lower portion of the collecting chamber comprises an outlet communicating with an exhaust pipe.

20. The multichamber thin-film deposition apparatus of claim 11, further a feed pipe providing one or more gases for the reactor chambers.
